(19) United States
(12) Patent Application Publication
(10) Pub. No.: US 2026/0107409 A1
(43) Pub. Date: Apr. 16, 2026

(54) COMPUTING CABINET AND RELATED COMPUTING SYSTEM

(71) Applicant: Tesla, Inc., Austin, TX (US)

(72) Inventors: Rishabh Bhandari, San Carlos, CA (US); William Chang, Mountain View, CA (US)

(21) Appl. No.: 19/115,738

(22) PCT Filed: Sep. 27, 2023
(86) PCT No.: PCT/US2023/033882

§ 371 Date: Mar. 26, 2025

Related U.S. Application Data
(60) Provisional application No. 63/377,942, filed on Sep. 30, 2022.

(51) Int. Cl. H05K 7/14; G06F 1/18; G06F 1/20; G06F 13/40; H05K 7/20

(52) U.S. Cl. CPC H05K 7/1492; G06F 1/189; G06F 1/20; G06F 13/4081; H05K 7/20645; G06F 2200/201

(57) ABSTRACT

Aspects of this disclosure relate to a computing cabinet for a computing system and to computing systems with one or more computing cabinets. The computing cabinet can include a power plane for power conversion, a compute plane, and a host plane. Computing cabinets disclosed herein can be modular and scalable. The computing cabinet can be configured such that components thereof can be hot swapped.

### CROSS-REFERENCE TO RELATED APPLICATION

This application claims the benefit of U.S. Provisional Ser. No. 63/377,942, titled “SYSTEM TRAY AND CABINET FOR COMPUTING SYSTEM,” filed Sep. 30, 2022, the disclosure of which is incorporated herein by reference in its entirety and for all purposes.

### BACKGROUND

### Technological Field

The present disclosure relates generally to computing systems, and more specifically to computing systems with one or more computing cabinets.

### Description of the Related Technology

Certain computing systems can be used in and/or specifically configured for high performance computing and/or computationally intensive applications, such as neural network training, neural network inference, machine learning, artificial intelligence, complex simulations, or the like. In some applications, a computing system can be used to perform neural network training. For example, such neural network training can generate data for an autopilot system for vehicle (e.g., an automobile), other autonomous vehicle functionality, or Advanced Driving Assistance System (ADAS) functionality.

In high performance computing systems, high-speed connectivity, desirable power performance, and dense integration are generally desirable. There can be a large number of parts and connections between parts in a high performance computing system. There are technical challenges associated with scaling certain high performance computing systems.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In one aspect, the techniques described herein relate to a computing cabinet. The computing cabinet can include a first section including a first power plane, a first compute plane configured to receive power from the first power plane and to perform computations, and a first host plane in communication with the first compute plane. The computing cabinet can include a second section including a second power plane, a second compute plane configured to receive power from the second power plane and to perform computations, and a second host plane in communication with the second compute plane. The second section is operable independently of the first section. The computing cabinet can include a cabinet frame. The first section and the second section are positioned within the cabinet frame.

In one embodiment, the first section is stacked vertically with the second section.

In one embodiment, the first compute plane, the first host plane, the second power plane, and the second host plane are positioned between the first power plane and the second power plane.

In one embodiment, at least a portion of the first power plane is hot swappable while the first compute plane operates.

In one embodiment, the first compute plane is hot swappable while the second compute plane operates.

In one embodiment, the first host plane is hot swappable while the second compute plane operates.

In one embodiment, the computing cabinet can include one or more redundant connections between the first power plane and the first compute plane.

In one embodiment, the computing cabinet can include an interface that includes a connection to an external power source and a coolant inlet. The connection to the external power source can be electrically connected to the first power plane and the second power plane. The coolant inlet is in fluid communication with the first compute plane and the second compute plane.

In one embodiment, the first compute plane includes a compute tray and a plurality of computing tiles positioned on the compute tray, and each computing tile of the plurality of computing tiles includes a plurality of dies and a cooling solution integrated with the plurality of dies.

In one embodiment, the first power plane includes a plurality of power trays configured to convert external power to power for the first compute plane.

In one embodiment, an individual power tray of the plurality of power trays is hot swappable while other power trays of the plurality of power trays operate.

In one embodiment, the computing cabinet can include connectors extending from the first compute plane and configured to connect with a compute plane of an adjacent cabinet.

In one embodiment, the computing cabinet can include blind cooling connectors on a side of the cabinet frame and blind power connectors on the side of the cabinet frame, wherein the first computing plane is connected to the blind cooling connectors and the blind power connectors upon insertion into the computing cabinet.

In one aspect, the techniques described herein relate to a computing system including. The computing system can include a first computing cabinet including a first power plane, a first compute plane configured to receive power from the first power plane and to perform computations, and a first host plane in communication with the first compute plane. The computing system can include a second computing cabinet including a second power plane, a second compute plane configured to receive power from the second power plane and to perform computations, and a second host plane in communication with the second compute plane. The first compute plane can be connected to the second compute plane by connectors that extend through a side of the first computing cabinet and a side of the second computing cabinet. A position of the first compute plane can be aligned with a position of the second compute plane.

In one embodiment, the connectors connecting the first compute plane and the second compute plane are blind connectors.

In one embodiment, the first computing cabinet can further include a third compute plane. The second computing cabinet can further include a fourth compute plane. The third compute plane can be connected to the fourth compute plane by second connectors that extend through the side of the first computing cabinet and the side of the second computing cabinet. A position of the third compute plane can be aligned with a position of the fourth compute plane.

In one embodiment, the first computing cabinet further includes a third power plane configured to provide power to the third compute plane, and a third host plane in communication with the third compute plane. the second computing cabinet further includes a fourth power plane configured to provide power to the fourth compute plane, and a fourth host plane in communication with the fourth compute plane.

In one embodiment, the first power plane includes a plurality of power trays, and an individual power tray of the plurality of power trays is hot swappable.

In one embodiment, the first computing cabinet further includes one or more redundant connections between the first power plane and the first compute plane.

In one embodiment, at least one of the first power plane and the first host plane is hot swappable.

In one embodiment, the first computing cabinet and the second computing cabinet are each independently operable.

In one embodiment, the computing system further includes a third computing cabinet including a third power plane, a third compute plane configured to receive power form the third power plane and to perform computations, and a third host plane in communication with the third compute plane. The first compute plane is connected to the third compute plane by third connectors that extend through a second side of the first computing cabinet and a side of the third computing cabinet. The first compute plane, the second compute plane and the third compute plane are connected.

In one embodiment, the computing system further includes a third computing cabinet connected to the second computing cabinet by only connectors extending from a second side of the second computing cabinet. The third computing cabinet includes third connectors extending from a second side of the third computing cabinet for connecting with a fourth computing cabinet.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Specific implementations will now be described with reference to the following drawings, which are provided by way of example, and not limitation.

FIGS. 1A, 1B, and 1C illustrate a computing cabinet for use in a computing system according to an embodiment.

FIGS. 2A, 2B, and 2C illustrate a front view of a connection between two computing cabinets using blind connectors according to an embodiment.

FIG. 3 illustrates a perspective view of a computing cabinet according to an embodiment.

FIG. 4 illustrates a perspective view of two computing cabinets of a computing system according to an embodiment.

FIGS. 5A and 5B illustrate connections between a first compute tray of a first computing cabinet and a second compute tray of a second computing cabinet using blind connectors according to an embodiment.

FIG. 6 illustrates views of a power tray according to an embodiment.

FIG. 7 illustrates multiple power trays tethered together for active cooling according to an embodiment.

FIG. 8A illustrates an array of power trays according to an embodiment.

FIGS. 8B and 8C illustrate two arrays of power trays positioned in a computing cabinet according to an embodiment.

FIG. 9 illustrates power buses integrated into a cabinet frame according to an embodiment.

FIGS. 10A and 10B illustrate a compute tray according to an embodiment.

FIG. 11 illustrates a compute tray positioned vertically relative to a host according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As discussed above, certain computing systems can be used in and/or specifically configured for high performance computing and/or computationally intensive applications, such as neural network training, neural network inference, machine learning, artificial intelligence, complex simulations, or the like. In some applications, a computing system can be used to perform neural network training. For example, such neural network training can generate data for an autopilot system for a vehicle (e.g., an automobile), other autonomous vehicle functionality, or Advanced Driving Assistance System (ADAS) functionality.

Certain computing systems can include various levels of hierarchy to perform computing tasks. For example, a computing system can include chips, computing tiles that each include a plurality of chips packaged together and integrated with cooling solutions, compute trays that include an array of connected computing tiles, power sources to deliver power to the various components, and computing cabinets that each include one or more compute tray(s) and one or more power source(s).

This disclosure relates to new computing systems. Computing systems described herein can be configured for high performance computing applications. Computing systems described herein can include hot swappable components that can be removed and/or inserted into the computing system while the computing system is actively powered and operating. For example, the hot swappable components can include compute trays and power trays that can be removed and/or replaced from the computing system without powering down the computing system. Each computing cabinet can have hot swappable power supplies. A computing cabinet can include two half cabinet sections that work independently of each other. Compute, power, and host for one half can be hot swapped without affecting the other half. Cabinets can include blind connects to enable such hot swaps of components without interacting with power connections to ensure safety during a hot swap. Blind connects, as described herein, can refer to connections that are capable of coupling to components without direct user access. Computing systems described herein can continue to operate when various components fail.

Computing systems are disclosed with self-contained computing cabinets. Each computing cabinet can have its own power conversion, host, and compute plane. Each computing cabinet can be fully functional by itself when receiving power and cooling.

Computing cabinets disclosed herein are modular and scalable. Each computing cabinet can be connected with an adjacent cabinet without any external parts. Blind connects are added to one side of each computing cabinet. An opposing side of the computing cabinet can fit with another computing cabinet to continuously scale the computing system. Computing cabinets can be used by themselves or joined to one or more other cabinets to scale to form as large a compute plane as desired for a computing task (e.g., training of different models).

Computing cabinets disclosed herein can have power redundancy. Each computing cabinet can have built in power redundancy in case there is a failed part, the failed part may not affect functionality of other components of the computing cabinet.

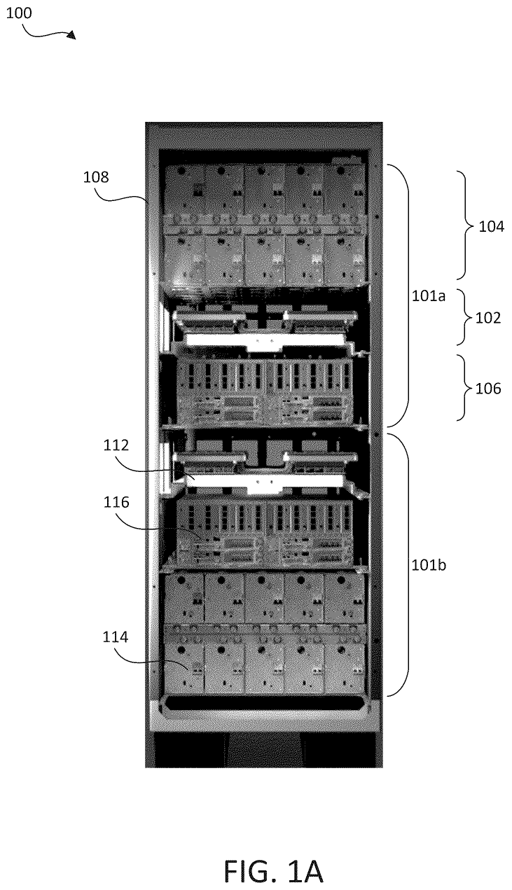

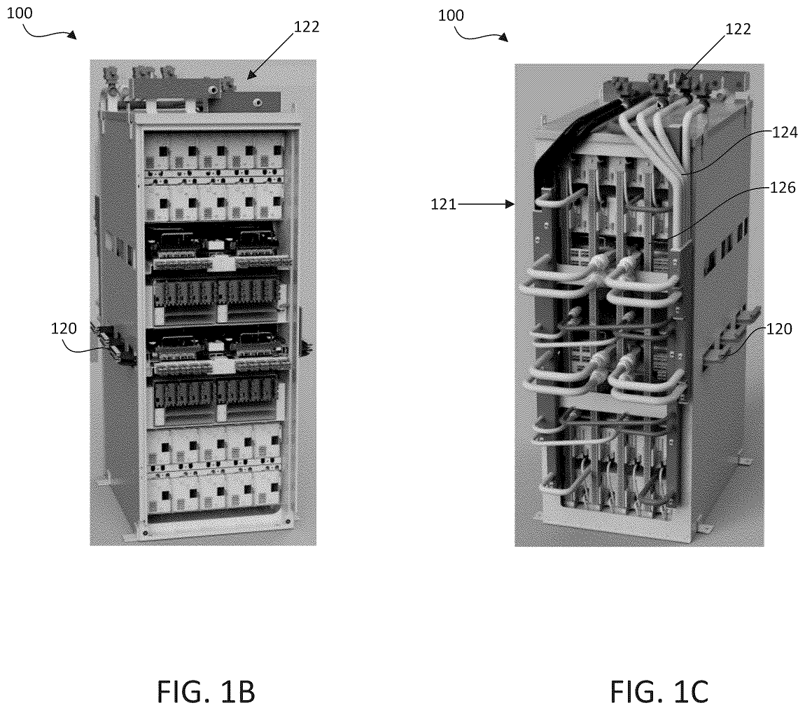

FIGS. 1A, 1B, and 1C illustrate a computing cabinet 100 for use in a computing system according to an embodiment. The computing cabinet 100 can operate as a fully functional computing system or can be connected to one or more other computing cabinets to increase the computing capabilities of the computing system. The computing cabinet 100 can be fully functional on its own when powered and cooled. The computing cabinet 100 receives power and cooling. The computing cabinet 100 distributes power and cooling to the various components housed in the structure of the computing cabinet 100.

As illustrated in FIG. 1A, the computing cabinet 100 may be divided into a first section 101a and a second section 101b, each containing a power plane 104, a compute plane 102, and a host plane 106. In some embodiments, the first section 101a and the second section 101b can operate independently of each other. As such, components of the first section 101a can be hot-swapped without affecting the operation of the second section 101b.

Each power plane 104 receives a high voltage input power and converts the input power to meet the specifications of the various other computing cabinet 100 components (e.g., a compute tray 112). Each power plane 104 can include an array of power trays 114. Each power tray 114 can operate in concert with the other power trays 114 of the power plane 104 to meet the specifications of the computing cabinet 100 section, such as the first section 101a or the second section 101b. As such, if a first power tray 114 fails, the other power trays 114 of the power plane 104 can compensate for the failure before the failed first power tray 114 is replaced. A power tray 114 can be removed and replaced from the power plane 104 without deactivating the power plane 104 and/or without disconnecting the power plane 104 from the high voltage input power.

Each compute plane 102 includes a compute tray 112 comprising one or more computing tiles. The computing tiles each include a plurality of chips or dies that are packaged together and integrated with one or more cooling solutions. In certain applications, a computing tile can include a system on a wafer that includes an array of dies. In some such applications, a cold plate can be integrated with the system on a wafer. A compute plane 102 can be used in and/or specifically configured for high performance computing and/or computationally intensive applications, such as neural network training, neural network inference, machine learning, artificial intelligence, complex simulations, or the like. In some applications, the compute plane 102 can be used to perform neural network training. For example, such neural network training can generate data for an autopilot system for a vehicle (e.g., an automobile), other autonomous vehicle functionality, or Advanced Driving Assistance System (ADAS) functionality. Compute planes 102 can operate individually and/or can be connected to compute planes 102 in one or more other computing cabinets 100 to increase the computing power of the computing system. For example, multiple compute planes 102 can be connected to scale the compute plane as desired for providing a higher capacity computing system. With higher capacity, the computing system can (1) execute a higher complexity computing task (e.g., train a more demanding model) and/or (2) run a higher number of computing tasks in parallel with each other.

Each host plane 106 includes a host tray 116. The host tray 116 can implement ingest processing for the compute plane 102 of the same section of the computing cabinet section, such as the first section 101a or the second section 101b. The host tray 116 can include Peripheral Component Interconnect Express (PCIe) connectivity to interface processors. The host tray 116 can provide video decoder support. In some embodiments, the host tray 116 can operate in an ×86 Linux environment.

As illustrated in FIG. 1A, the computing cabinet 100 includes a first compute tray 112 positioned vertically over a first host tray 116 and a second compute tray 112 positioned vertically over a second host tray 116. The first host tray 116 can be positioned between the first compute tray 112 and the second compute tray 112 as illustrated. The power trays 114 can be included at the top and bottom of the computing cabinet 100 and positioned vertically relative to the compute trays 112 and host trays 116.

FIG. 1B illustrates the computing cabinet 100 of FIG. 1A from a front view and FIG. 1C illustrates the computing cabinet 100 from a back view. As illustrated in FIGS. 1B and 1C, the computing cabinet 100 can include blind connectors 120, a coolant interface 122, a power interface 121, a coolant distribution system 124, and power buses 126. The power interface 121 can include connections to external power. The external power source can be a high voltage power source with sufficient power rating to power the computing cabinet 100. The power trays 114 can receive power from the power interface 121. The coolant interface 122 can include connections to an external cooling source. The external cooling source can be a connection to a source of a fluid, such as coolant, that can be distributed throughout the computing cabinet 100 to help maintain a sufficiently low operating temperature.

The coolant distribution system 124 can carry a coolant to and from the interface 122 and distribute the coolant to the computing cabinet 100 components, such as to the power trays 114, the compute trays 112, and host trays 116. The coolant distribution system 124 can also output coolant from the computing cabinet 100. The coolant distribution system 124 can include one or more hoses, one or more manifolds, one or more coolant connections, the like, or any suitable combination thereof to facilitate coolant flow within the computing cabinet 100.

The power buses 126 can include electrical conductors and/or electrical connection points. The power buses 126 can carry converted power from the power trays 114 to the other cabinet components, such as to the compute tray 112 and host trays 116. The power buses 126 can include redundant electrical connections. For example, a compute tray 112 can be connected to power trays 114 through multiple electrical connections. As such, if a power tray 114 fails or is removed, the compute tray 112 can receive power from one or more other power trays 114.

As is illustrated in FIG. 1C, the coolant distribution system 124 and the power buses 126 can be positioned at the back of the computing cabinet. As will be described, the various components of the computing cabinet 100 can include blind connectors that allow for the components to be connected to the coolant distribution system 124 and the power buses 126 without a user making manual connections. For example, when a compute tray 112 is fully inserted into the computing cabinet 100, blind cooling connectors can be inserted into the coolant distribution system 124 and blind power connectors can be inserted into the power buses 126 at the back of the computing cabinet 100.

The computing cabinet 100 includes a cabinet frame 108. The cabinet frame 108 provides the structural support for the various components, such as support rails for the compute trays 112, power trays 114, and host trays 116. The coolant distribution system 124, the power buses 126, and the interface 122 can be integrated into the cabinet frame 108. As such, physical support for a component can be established along with a connection to the coolant distribution system 124 and the power buses 126 in a single action. For example, when a compute tray 112 is fully inserted into the computing cabinet 100, the compute tray 112 may be physically coupled to the cabinet frame 108 as well as being connected to the coolant distribution system 124 and the power buses 126.

The blind connectors 120 can connect a first compute tray 112 of a first computing cabinet 100 to a second computing tray 112 of a second computing cabinet 100, allowing the computing planes 102 of the two computing cabinets 100. In some instances, the length of a connection between computing trays 112 may contribute to a loss of computing capability. As such, connected computing trays 112 of adjacent computing cabinets 100 may have increased computing capability the closer the connected computing trays 112 are situated. To facilitate a closer connection, the blind connectors 120 may enable computing trays 112 of adjacent computing cabinets 100 to be connected blindly and/or without physical access to the blind connectors 120. The blind connectors 120 will be described in more detail below.

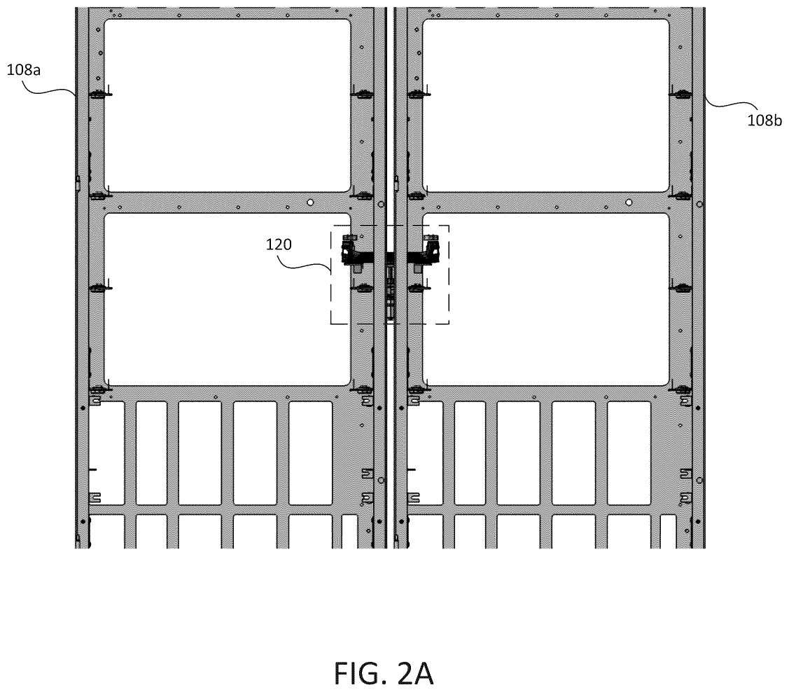

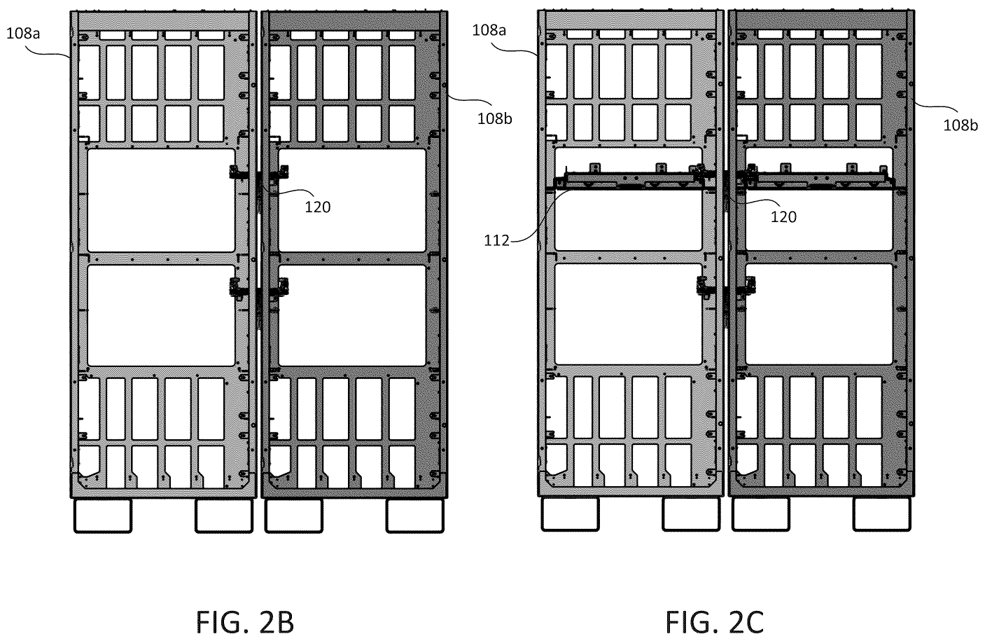

FIGS. 2A, 2B, and 2C illustrate a front view of a connection between two computing cabinets 100 using blind connectors 120 according to an embodiment. FIGS. 2A and 2B illustrate blind connectors 120 spanning a first cabinet frame 108a and a second cabinet frame 108b before computing trays are positioned within the cabinet frames 108a, 108b. As illustrated in FIGS. 2A and 2B, minimal space may be present between the first cabinet frame 108a and the second cabinet frame 108b. In some embodiments, no space may be present between the first cabinet frame 108a and the second cabinet frame 108b. As such, it may be difficult or impossible to access the blind connectors 120 from outside the first cabinet frame 108a or second cabinet frame 108b. Further, while not shown in FIG. 2A or 2B, the first cabinet frame 108a and second cabinet frame 108b can include components, such as compute trays 112, power trays 114, and host trays 116, that occupy most of the space within the cabinet frames 108a and 108b. As such, it may be difficult to access the blind connectors 120 for inside the first cabinet frame 108a or second cabinet frame 108b.

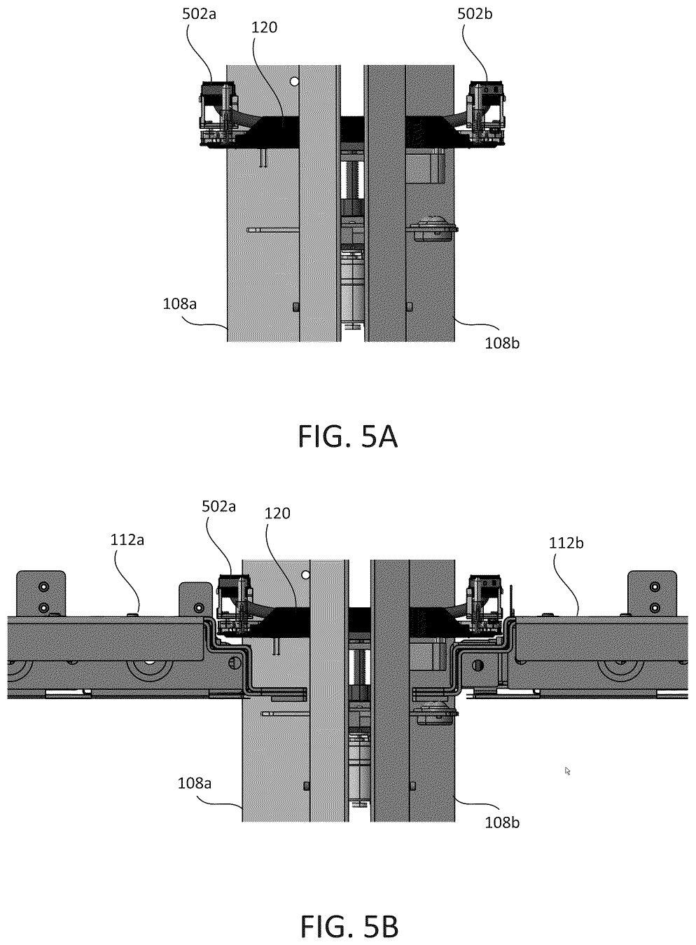

FIG. 2B illustrates cabinet frames 108a and 108b each having one computing tray 112 positioned therein. The blind connectors 120 can connect compute trays 112 between adjacent computing cabinets, for example as shown in FIG. 2C, without direct access to the blind connectors 120. Although FIG. 2C illustrates one computing tray 112 in each cabinet frame 108a, 108b, two or more compute trays 112 can be included in a single computing cabinet. An example of compute trays 112 connected using blind connectors 120 is shown in FIGS. 5A and 5B and discussed in more detail below.

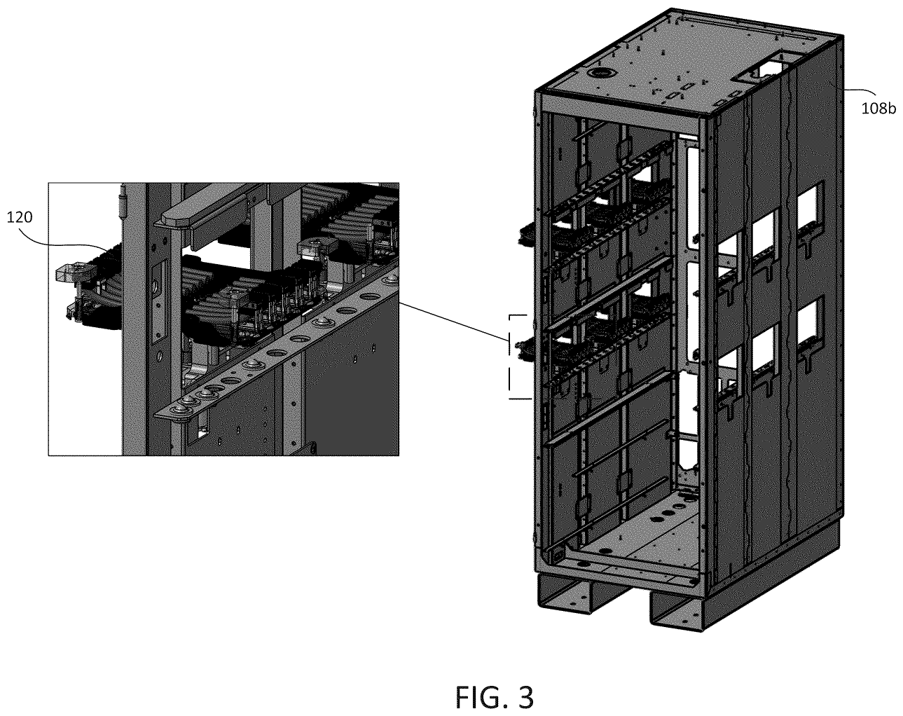

FIG. 3 illustrates a perspective view of a single computing cabinet according to an embodiment. FIG. 3 illustrates a perspective view of the second cabinet frame 108b of FIG. 2A with blind connectors 120 extending out of the second cabinet frame 108b. As illustrated in FIG. 3, the blind connectors 120 may contain multiple groups of connectors. For example, FIG. 3 illustrates six groups of connectors for the blind connectors 120 that extend from the cabinet frame 108b. There are two sets of three groups of correctors extending from the cabinet frame 108b in FIG. 3. Each group of connectors can connect to a respective computing tile that is positioned on a compute tray 112. The blind connectors 120 shown in FIG. 3 can connect to 3 computing tiles on a first computing tray 112 and three computing tiles on a second computing tray 112. The number of groups of connectors of the blind connectors 120 can vary based on the number of computing tiles connected by the blind connectors 120.

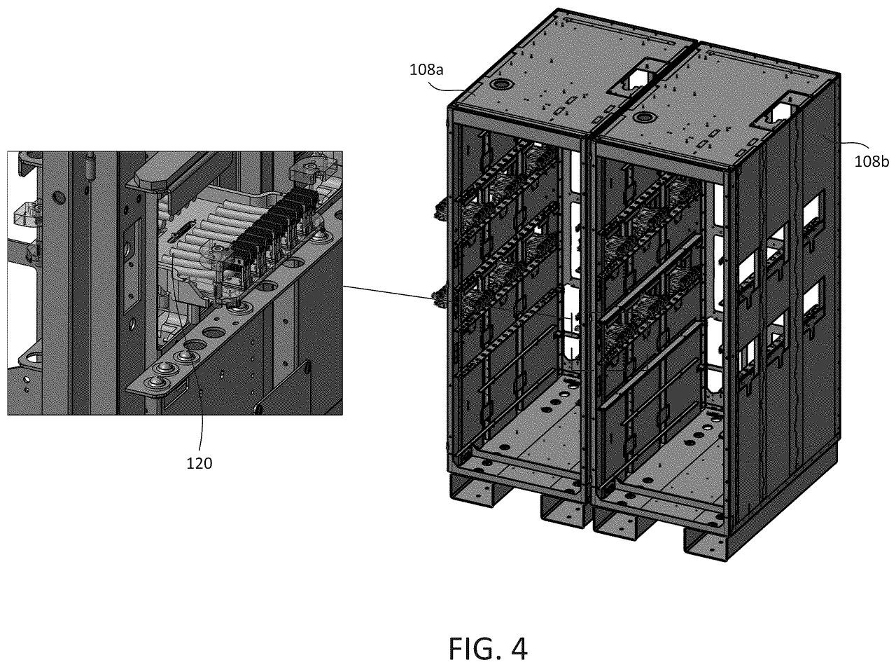

FIG. 4 illustrates a perspective view of two computing cabinets according to an embodiment. FIG. 4 illustrates a perspective view of the first cabinet frame 108a and second cabinet frame 108b of FIG. 2A with blind connectors 120 extending out of one side of the first cabinet frame 108a into the second cabinet frame 108b and out of the opposite side of the cabinet frame 108a. While not shown in FIG. 4, a third cabinet frame 108 may be positioned on the opposite side of the first cabinet frame 108a than the second cabinet frame 108b and connected by blind connectors 120. Any suitable number of computing cabinets 100 can be connected in this manner. Such connections along with modular and self-sufficient cabinets can enable scalable computing systems.

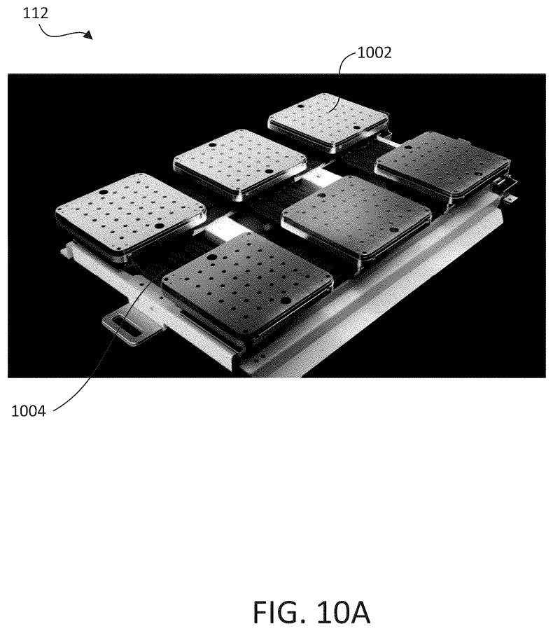

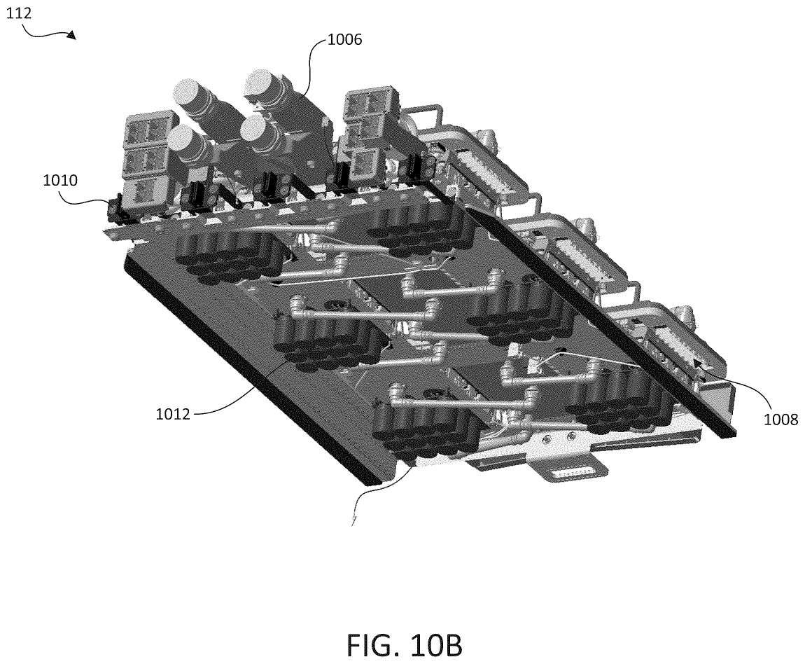

FIGS. 5A and 5B illustrate the connection of a first compute tray 112a and a second compute tray 112b using blind connectors 120 according to an embodiment. Referring to FIG. 5A, blind connectors 120 are shown extending into a first cabinet frame 108a and a second cabinet frame 108b. The blind connectors 120 includes a first connection interface 502a and a second connection interface 502b. The first connection interface 502a and the second connection interface 502b can each include a plurality of connectors that can be electrically coupled to corresponding connectors on a compute tray 112, such as the inter-tray tile connectors 1008 of FIG. 10B. The first connection interface 502a and the second connection interface 502b can include actuators that allow the first connection interface 502a and the second connection interface 502b to toggle between a connected and disconnected position.

When the first connection interface 502a and the second connection interface 502b are in a disconnected position, the blind connector 120 can be positioned out of the installation path of compute trays 112 in the first cabinet frame 108a and the second cabinet frame 108b, such that compute trays 112 can be inserted into the first cabinet frame 108a and the second cabinet frame 108b. When the first connection interface 502a and the second connection interface 502b are in a connected position, the blind connector 120 can be positioned in the installation path of the compute trays 112 and/or coupled to the compute trays 112 in the first cabinet frame 108a and the second cabinet frame 108b.

Referring to FIG. 5B, a blind connector 120 is shown extending into the first cabinet frame 108a and the second cabinet frame 108b and coupled to a first compute tray 112a and a second compute tray 112b. Certain hardware of the first compute tray 112a and second compute tray 112b, such as the inter-tray tile connectors 1008 of FIG. 10B, is omitted from FIG. 5B. As the first compute tray 112a is first inserted into a first cabinet frame 108a, the first connection interface 502a may be actuated downward into the disconnected position. When the first compute tray 112a is fully inserted into the first cabinet frame 108a, the first connection interface 502a may be actuated upward into the connected position, coupling the first connection interface 502a to the first compute tray 112a.

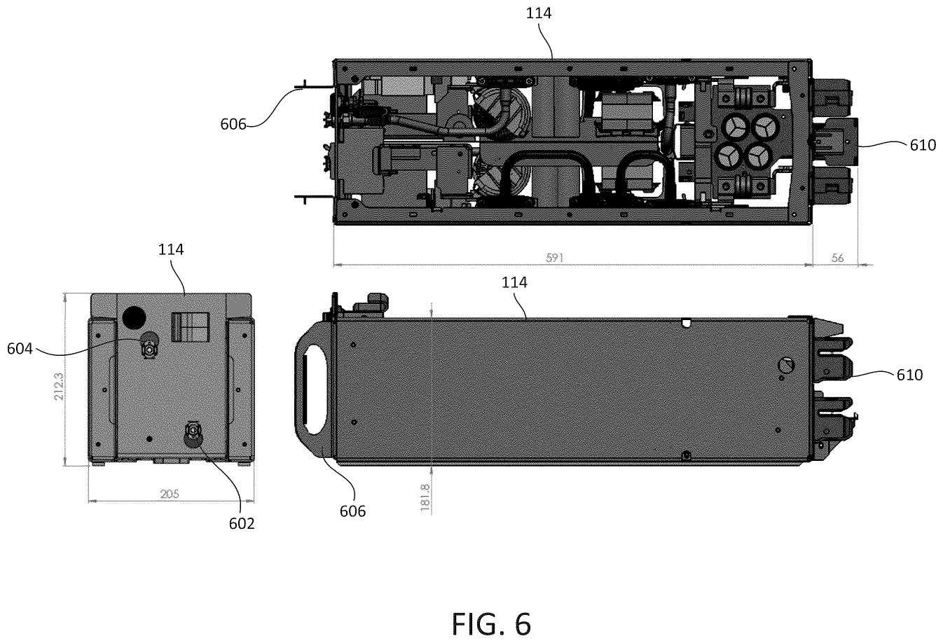

FIG. 6 illustrates views of a power tray 114 according to an embodiment. The power tray 114 of FIG. 6 can implement the power tray 114 of FIG. 1A, for example. The power tray 114 can include a coolant inlet 602, a coolant outlet 604, and a power handle 606 located on the first end of the power tray 114. The power tray 114 can include blind power connectors 610 located on the second end of the power tray 114, where the second end is opposite the first end. The first end can be a front end, and the second end can be a back end.

The coolant inlet 602 can connect one or more internal coolant manifolds of the power tray 114 to a coolant source, such as the coolant distribution system 124 of FIG. 1C. The internal coolant manifolds can distribute coolant throughout the power tray 114 to actively cool the power tray 114. The coolant outlet 604 can be connected to one or more the internal coolant manifolds of the power tray 114 and discharge coolant to a coolant destination, such as the coolant distribution system 124 of FIG. 1C.

The blind power connectors 610 can electrically and physically couple to a power source and/or deliver power to a power destination. For example, the blind power connectors 610 can receive a high voltage input power and provide the input power to the power tray 114. The power tray 114 can perform power conversion and deliver the converted power the power buses 126 to be used by the computing cabinet 100 components, such as a compute tray 112 and/or the host tray 116. The power tray 114 can include various internal electrical components, such as power converters, capacitors, resistors, inductors, transistors, the like, or any suitable combination thereof. In some embodiments, the internal electrical components allow the power tray 114 to be inserted into an actively powered computing cabinet 100 without damaging the power tray 114 or other components of the computing cabinet 100.

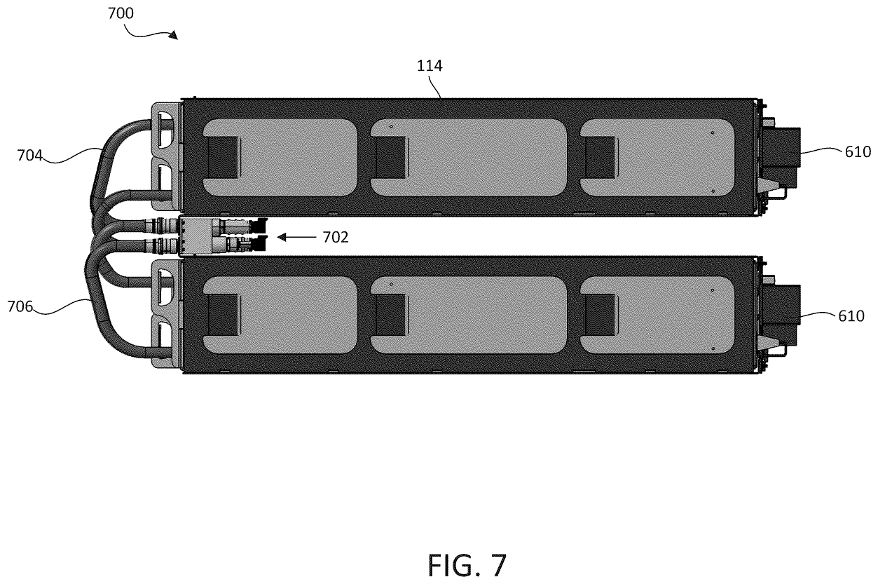

FIG. 7 illustrates multiple power trays 114 connected together for active cooling according to an embodiment. As illustrated in FIG. 7, coolant can be carried from the coolant distribution system 124 of FIG. 1C (not shown in FIG. 7) into the coolant connectors 702 positioned between the power trays 114. In some embodiments, a coolant inlet manifold can be positioned in between the power trays 114 to carry coolant from the coolant distribution system 124 positioned at the back of the two power trays 114. In some embodiments, a coolant outlet manifold can be positioned in between the power trays 114 discharge coolant to the coolant distribution system 124 positioned at the back of the two power trays 114.

As illustrated in FIG. 7, the coolant connectors 702 include a coolant input connector and a coolant output connector. From the coolant input connector, coolant can be carried by a coolant inlet hose 704 into coolant inlet 602 (not shown in FIG. 7) of the power trays 114. Discharged coolant can be carried from the coolant outlet 604 (not shown in FIG. 7) to the coolant output connector by the coolant outlet hose 706.

As illustrated in FIG. 7, each of the power trays 114 can have blind power connectors 610 positioned at the back of the power trays 114. In some embodiments, the blind power connectors 610 can be connected to the power buses 126 and the coolant connector 702 can be connected to the coolant distribution system 124 in the same operation. For example, when the power trays 114 are inserted into the cabinet frame 108, the blind power connectors 610 can be connected to the power buses 126 and the coolant connector 702 can be connected to the coolant distribution system 124 at the same time.

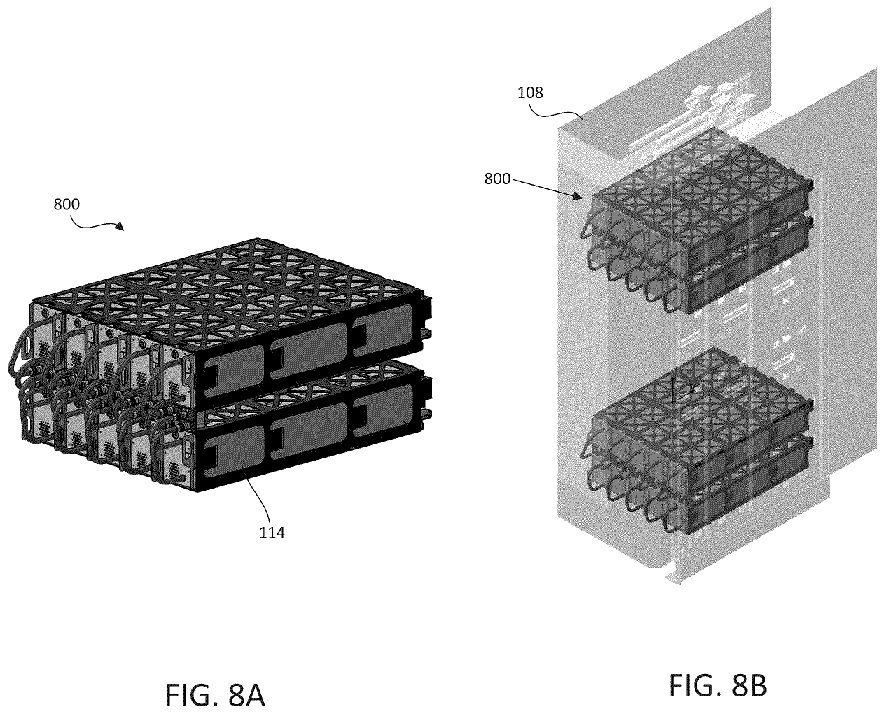

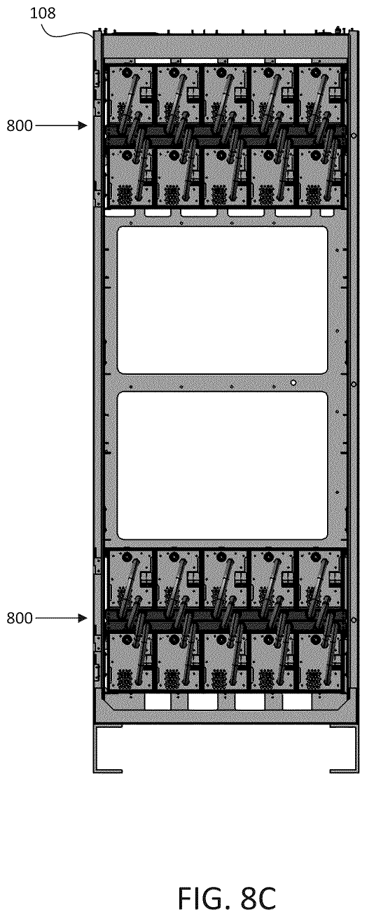

FIGS. 8A, 8B, and 8C illustrate an array of power trays 800 according to an embodiment. The array of power trays 800 can include multiple power trays 114. The array of power trays 800 can implement a power plane 104 of FIG. 1A, for example. As illustrated in FIG. 8B, an array of power trays 800 can be inserted into a cabinet frame 108 for use in a computing cabinet 100. Each power tray 114 of the array of power trays 800 may operate individually. For example, a single power tray 114 may fail or be removed from the array of power trays 800 without causing the array of power trays 800 to fail.

The array of power trays 800 may include redundant power trays 114. For example, operating a subset of the power trays 114 of the array of power trays 800 can meet a power specification of the computing cabinet 100. As illustrated in FIG. 8C, a cabinet frame 108 can house more than one array of power trays 800. For example, a first array of power trays 800 can power a first section of the computing cabinet 100 and a second array of power trays 800 can power a second section of the computing cabinet 100.

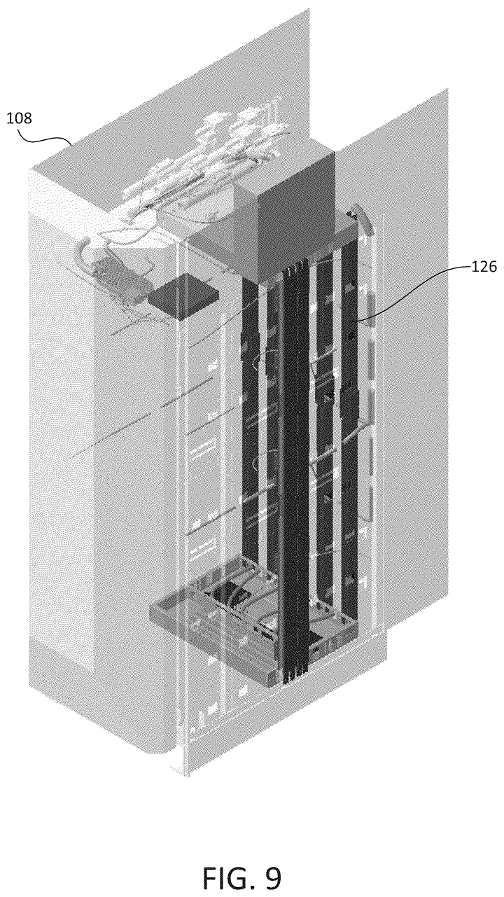

FIG. 9 illustrates power buses 126 integrated into a cabinet frame 108 according to an embodiment. As discussed above, the power buses 126 can include electrical conductors and electrical connection points. The power buses 126 can also carry converted power from the power trays 114 to the other cabinet components, such as the compute trays 112 and host trays 116. The power buses 126 can include one or more redundant electrical connections. For example, a compute tray 112 can be connected to power trays 114 through multiple electrical connections. As such, if an individual power tray 114 (or group of power trays 114) fails or is removed, the compute tray 112 can receive power from other power trays 114.

The power buses 126 can include a plurality of connection points. The connection points can be configured to couple with power connections from various components, such as the blind power connectors 610 of the power trays 114 (as discussed in FIG. 6) and the blind compute connector 1010 of the compute tray 112 (as discussed in FIG. 10B).

FIGS. 10A and 10B illustrate an example compute tray 112 according to an embodiment. The compute tray 112 can include an array of computing tiles 1002 connected together and supported by the compute tray 112. In certain embodiments, each computing tile 1002 includes a system on a wafer that includes an array of dies integrated with a cooling solution (e.g., a cold plate). For example, the system on a wafer can include 16, 25, 36, or 49 dies arranged to perform compute functions in various applications. According to certain applications, the system on a wafer can be positioned between a cold plate and another cooling component to dissipate heat, remove heat, or otherwise reduce the temperature of components of a computing tile 1002 during operation. The computing tiles 1002 can be referred to as training tiles in neural network training applications. Each computing tile 1002 of a compute tray 112 can operate individually. As such if a computing tile 1002 of a compute tray 112 fails and/or is removed from the compute tray 112, the compute tray 112 can continue to operate. Any suitable number of computing tiles 1002 can be connected to each other on a compute tray 112. For example, FIG. 10A illustrates six computing tiles 1002 connected to each other.

The compute tray 112 can have a high compute capacity. For example, the compute tray 112 can perform over 50 peta-floating point operations per second (PFLOPS). In certain applications, the compute tray can perform in a range from 50 PFLOPS to 200 PFLOPS.

The compute tray 112 can include intra-tray signal delivery cables 1004 to facilitate communication between each computing tile 1002 and/or connectors 1008 of a computing tile 1002. The intra-tray signal delivery cables 1004 can include one or more redundant connections. For example, the computing tiles 1002 can be connected together through multiple intra-tray signal delivery cables 1004. As such, if an intra-tray signal delivery cable 1004 fails and/or is removed, and/or a computing tile 1002 fails and/or is removed, the compute tray 112 can continue to operate.

In the computing tray 112, adjacent computing tiles 1002 are connected to each other by intra-tray signal delivery cables 1004. If a computing tile 1002 fails, other computing tiles 1002 on the computing tray 112 can still function. For instance, an adjacent computing tile 1002 can route signals around the failed computing tile 1002 to functional computing tile(s) to perform computation tasks and/or to route signals around the failed computing tile 1002.

Referring to FIG. 10B, the computing tiles 1002 can include connectors 1008 around their edges. The connectors 1008 of the computing tiles 1002 can be connected to blind connectors to connect computing tiles 1002 of two compute trays 112 together with each other. For example, the connectors 1008 can be connected to connection interfaces, such as the first connection interface 502a and/or the second connection interface 502b of FIG. 5B, such that a computing tile 1002 in a first computing cabinet 100 and a second the computing tile 1002 in a second computing cabinet 100 are connected.

The compute tray 112 can include compute cooling connectors 1006. Certain compute cooling connectors 1006 can receive coolant and provide the coolant to the compute tray 112 to cool the compute tray 112 components, such as the computing tiles 1002. Other compute cooling connectors 1006 can discharge coolant from the compute tray 112. The compute cooling connectors 1006 can be connected to the coolant distribution system 124 of FIG. 1C, for example. For example, certain compute cooling connectors 1006 can receive coolant from the coolant distribution system 124 and other compute cooling connectors 1006 discharge coolant into the coolant distribution system 124. The compute cooling connectors 1006 can be positioned at the back of the compute tray 112 such that the cooling connectors 1006 connect to the coolant distribution system 124 when the compute tray 112 is fully inserted into the computing cabinet 100.

The compute tray 112 can include a blind compute connector 1010 configured to connect the compute tray 112 to a power source. For example, the blind compute connector 1010 can be inserted into the power buses 126 of FIG. 1C and receive power from the power trays 114. The blind compute connector 1010 can be positioned at the back of the compute tray 112. As such, the compute tray 112 can be inserted safely into an active power source, such as the power buses 126, when the compute tray 112 is fully inserted into the computing cabinet 100.

As illustrated in FIG. 10B, the compute tray 112 can include capacitor boards 1012. The capacitor boards 1012 may allow the compute tray 112 to be safely hot swapped from a powered computing cabinet 100. For example, the capacitor boards 1012 can allow a compute tray 112 to be removed from and/or inserted into an active power source without damaging the compute tray 112 components, such as the computing tiles 1002.

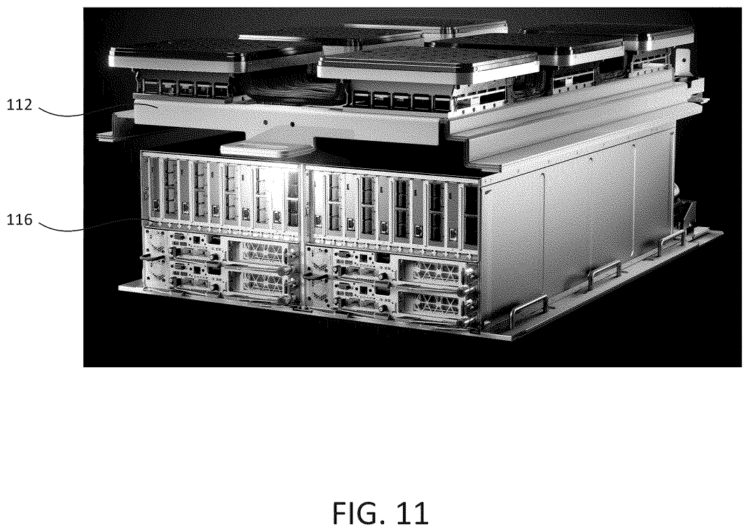

FIG. 11 illustrates a compute tray 112 positioned above a host tray 116 according to an embodiment. As described above, the host tray 116 can implement ingest processing for the compute tray 112 alone, or in combination with additional compute trays 112 in a compute plane 102. The host tray 116 can include Peripheral Component Interconnect Express (PCIe) connectivity to interface processors. The host tray 116 can provide video decoder support. In some embodiments, the host tray 116 can operate in an ×86 Linux environment. The vertical stacking of the compute tray 112 and the host tray 116 can efficiently utilize space to enable dense integration with minimal connection lengths between computing trays of adjacent cabinets.

In certain applications, the modular design of a compute cabinet can allow a first section of the compute cabinet to continue operating while a host tray 116 of a second section of the compute cabinet has a failure, is being fixed, or is otherwise offline. Including a compute tray 112 and a host tray 116 paired with each other in a modular compute cabinet design can enable such features.

In some embodiments, multiple host trays 116 can implement ingest processing for a compute plane 102. As such, a host tray 116 may fail and/or be removed from the computing system and the compute plane 102 may continue to operate. Further a compute plane 102 can be partitioned into multiple operations with one or more host trays 116 implementing ingest processing for each partitioned operation.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

1. A computing cabinet comprising:
a first section comprising a first power plane, a first compute plane configured to receive power from the first power plane and to perform computations, and a first host plane in communication with the first compute plane;
a second section comprising a second power plane, a second compute plane configured to receive power from the second power plane and to perform computations, and a second host plane in communication with the second compute plane; wherein the second section is operable independently of the first section; and
a cabinet frame, wherein the first section and the second section are positioned within the cabinet frame.

2. The computing cabinet of claim 1, wherein the first section is stacked vertically with the second section.

3. The computing cabinet of claim 2, wherein the first compute plane, the first host plane, the second power plane, and the second host plane are positioned between the first power plane and the second power plane.

4. The computing cabinet of claim 1, wherein at least a portion of the first power plane is hot swappable while the first compute plane operates.

5. The computing cabinet of claim 1, wherein the first compute plane is hot swappable while the second compute plane operates.

6. The computing cabinet of claim 1, wherein the first host plane is hot swappable while the second compute plane operates.

7. The computing cabinet of claim 1, further comprising one or more redundant connections between the first power plane and the first compute plane.

8. The computing cabinet of claim 1, further comprising an interface that includes a connection to an external power source and a coolant inlet, wherein the connection to the external power source is electrically connected to the first power plane and the second power plane, and wherein the coolant inlet is in fluid communication with the first compute plane and the second compute plane.

9. The computing cabinet of claim 1, wherein the first compute plane comprises a compute tray and a plurality of computing tiles positioned on the compute tray, and each computing tile of the plurality of computing tiles comprises a plurality of dies and a cooling solution integrated with the plurality of dies.

10. The computing cabinet of claim 1, wherein the first power plane comprises a plurality of power trays configured to convert external power to power for the first compute plane.

11. The computing cabinet of claim 10, wherein an individual power tray of the plurality of power trays is hot swappable while other power trays of the plurality of power trays operate.

12. The computing cabinet of claim 1, further comprising connectors extending from the first compute plane and configured to connect with a compute plane of an adjacent cabinet.

13. The computing cabinet of claim 1, further comprising blind cooling connectors on a side of the cabinet frame and blind power connectors on the side of the cabinet frame, wherein the first computing plane is connected to the blind cooling connectors and the blind power connectors upon insertion into the computing cabinet.

14. A computing system comprising:
a first computing cabinet comprising a first power plane, a first compute plane configured to receive power from the first power plane and to perform computations, and a first host plane in communication with the first compute plane; and
a second computing cabinet comprising a second power plane, a second compute plane configured to receive power from the second power plane and to perform computations, and a second host plane in communication with the second compute plane;
wherein the first compute plane is connected to the second compute plane by connectors that extend through a side of the first computing cabinet and a side of the second computing cabinet, and wherein a position of the first compute plane is aligned with a position of the second compute plane.

15. The computing system of claim 14, wherein the connectors connecting the first compute plane and the second compute plane are blind connectors.

16. The computing system of claim 14, wherein:
the first computing cabinet further comprises a third compute plane;
the second computing cabinet further comprises a fourth compute plane; and
wherein the third compute plane is connected to the fourth compute plane by second connectors that extend through the side of the first computing cabinet and the side of the second computing cabinet, and wherein a position of the third compute plane is aligned with a position of the fourth compute plane.

17. The computing system of claim 16, wherein:
the first computing cabinet further comprises a third power plane configured to provide power to the third compute plane, and a third host plane in communication with the third compute plane; and
the second computing cabinet further comprises a fourth power plane configured to provide power to the fourth compute plane, and a fourth host plane in communication with the fourth compute plane.

18. The computing system of claim 14, wherein the first power plane includes a plurality of power trays, and an individual power tray of the plurality of power trays is hot swappable.

19. The computing system of claim 14, wherein the first computing cabinet further comprises one or more redundant connections between the first power plane and the first compute plane.

20. (canceled)

21. The computing system of claim 14, wherein the first computing cabinet and the second computing cabinet are each independently operable.

22. (canceled)

23. (canceled)
